(19) United States
(12) Patent Application Publication
(10) Pub. No.: US 2025/0089271 A1
(43) Pub. Date: Mar. 13, 2025

(54) MEMORY DIE STACK HAVING A SWITCH FOR SELECTIVELY CONNECTING A MEMORY DIE TO A SUBSTRATE

(71) Applicant: Western Digital Technologies, Inc., San Jose, CA (US)

(72) Inventors: Nagesh Vodrahalli, Los Altos, CA (US); Dmitry Vaysman, San Jose, CA (US); Md. Sayed Mobin, San Jose, CA (US); John Randall, Fremont, CA (US); Narayanan Terizhandur V, Bothell, WA (US)

(21) Appl. No.: 18/463,805

(22) Filed: Sep. 8, 2023

(51) Int. Cl. H10B 80/00; H01L 25/065

(52) U.S. Cl. CPC H10B 80/00; H01L 25/0657; H01L 2225/06506; H01L 2225/0651; H01L 2225/06562

(57) ABSTRACT

A memory device includes a stack of memory die packages. Each memory die package includes at least two memory dies. A switch is electrically coupled to at least one of the memory die packages. A bond wire electrically couples the switch to a substrate of the memory device. Each memory die is also electrically coupled to the switch. Based on a received control signal, the switch selects which memory die is electrically and/or communicatively coupled to the substrate using the electrical connections between the memory dies and the bond wire that electrically couples the switch to the substrate.

### BACKGROUND

Semiconductor memory and storage devices are widely used in various electronic devices such as cellular telephones, digital cameras, personal digital assistants, medical electronics, mobile computing devices, and non-mobile computing devices. Semiconductor memory may include non-volatile memory or volatile memory. Examples of non-volatile memory include flash memory (e.g., NAND-type and NOR-type flash memory) and Electrically Erasable Programmable Read-Only Memory (EEPROM).

NAND-type memory packages typically include one or more input/output (I/O) data channels from, for example, a substrate of a ball grid array (BGA) package through one or more stacked NAND memory dies (e.g., for greater storage capacity). Each of these I/O data channels is typically serially connected from the substrate to each of the memory dies using a bond wire that connects a pin cap on the substrate to a pin cap on the memory die (e.g., an input pin or memory pad), or from pin cap on one memory die to a pin cap on another memory die. The I/O data channel acts as a transmission line that connects portions of all of the memory dies to the BGA package. However, typical I/O data channels with this conventional bond wire architecture cause a bandwidth restriction on the I/O channel as the I/O data channel supports multiple different memory dies in the stack.

Accordingly, it would be beneficial for each memory die in a stack to individually and/or separately access a particular I/O data channel.

### SUMMARY

The present application describes a memory device having a stack of memory die packages. In an example, each memory die package includes at least two memory dies that are bonded together. A switch is electrically and/or communicatively coupled to a top surface of one or more memory die packages. The switch enables each memory die in each memory die package to have individual access to an I/O data channel associated with the stack of memory die packages. For example, each memory die in each of the memory die packages is communicatively and/or electrically coupled (e.g., using a bond wire, a through silicon via (TSV)) to the switch. A bond wire electrically couples the switch to a substrate of the memory device. Based on a received control signal, the switch selects which memory die is electrically and/or communicatively coupled to the substrate. This arrangement increases the overall electrical performance of the I/O data channel and the memory device when compared with conventional bond wire architectures.

Accordingly, one example of the present application describes a memory device that includes a first memory die package and a second memory die package. The first memory die package includes a first memory die bonded with a second memory die. Likewise, the second memory die package includes a third memory die bonded with a fourth memory die. Additionally, the first memory die package and the second memory die package form a stack of memory die packages. The memory device also includes a switch electrically coupled to a top surface of the first memory die package. A first electrical connection electrically couples the first memory die to the switch, a second electrical connection electrically couples the second memory die to the switch, a third electrical connection electrically couples the third memory die to the switch, and a fourth electrical connection electrically couples the fourth memory die to the switch. The memory device also includes a bond wire that electrically couples the switch to a substrate of the memory device.

The present application also describes a semiconductor package that includes a first semiconductor die and a second semiconductor die that are bonded together to form a first package. The semiconductor package also includes a third semiconductor die and a fourth semiconductor die that are bonded together to form a second package. In an example, the second package is stacked with the first package. A switch is electrically coupled to a top surface of the first package and a plurality of electrical connections electrically couple the first semiconductor die, the second semiconductor die, the third semiconductor die and the fourth semiconductor die to the switch. A bond wire electrically couples the switch to a substrate of the semiconductor package.

In yet another example, the present application describes a memory device that includes a controller means, a first semiconductor package having a first semiconductor die bonded with a second semiconductor die and a second semiconductor package having a third semiconductor die bonded with a fourth semiconductor die. In an example, the second semiconductor package and the first semiconductor package are arranged in a stacked configuration. The memory device also includes a switching means electrically coupled to the first semiconductor package and the second semiconductor package. In an example, the switching means selectively electrically couples each of the first semiconductor die, the second semiconductor die, the third semiconductor die and the fourth semiconductor die to a substrate of the memory device using a bond wire that electrically couples the switching means to the substrate.

This summary is provided to introduce a selection of concepts in a simplified form that are further described below in the Detailed Description. This summary is not intended to identify key features or essential features of the claimed subject matter, nor is it intended to be used to limit the scope of the claimed subject matter.

### BRIEF DESCRIPTION OF THE DRAWINGS

Non-limiting and non-exhaustive examples are described with reference to the following Figures.

FIG. 1A illustrates a conventional bond wire architecture for a memory device.

FIG. 1B shows various graphs that illustrate bandwidth limitations of the bond wire architecture shown in FIG. 1A.

FIG. 2 is an example architecture of a memory device that includes a switch that selectively connects a memory die to a substrate according to an example.

FIG. 3A illustrates another example architecture of a memory device that includes a switch that selectively connects a memory die to a substrate according to an example.

FIG. 3B shows various graphs that illustrate bandwidth performance of the memory device shown in FIG. 3A.

FIG. 4 illustrates a switch and an integrated circuit being surface mounted to a memory die package according to an example.

### DETAILED DESCRIPTION

In the following detailed description, references are made to the accompanying drawings that form a part hereof, and in which are shown by way of illustrations specific embodiments or examples. These aspects may be combined, other aspects may be utilized, and structural changes may be made without departing from the present disclosure. Examples may be practiced as methods, systems or devices. Accordingly, examples may take the form of a hardware implementation, an entirely software implementation, or an implementation combining software and hardware aspects. The following detailed description is therefore not to be taken in a limiting sense, and the scope of the present disclosure is defined by the appended claims and their equivalents.

In some NAND memory devices, bond wires are used to create I/O data channels between a substrate of a memory device or a memory package (e.g., a BGA package) and multiple memory dies included in the memory device. Due to increased storage capacity needs, multiple memory dies may be stacked in a highly integrated, complex package system. For example, some memory devices or memory packages may include 2, 4, 8, or 16 memory dies in a single package. These memory dies may be integrated together into one or more I/O data channels using a “single-cap” bond wire architecture in which a pin cap of the package substrate is wired to a pin cap on the first memory die by way of a bond wire, then from the pin cap on the first memory die to a pin cap on a second memory die by way of another bond wire, and so on. However, because each memory die may share the same I/O data channel, the bandwidth on the I/O data channel is typically limited.

In order to address the above, the present application describes a memory device that enables each memory die in a stack of memory dies to individually access an I/O data channel of the memory device. In an example, the memory device includes multiple memory die packages. Each memory die package includes at least two memory dies that are bonded together. A switch is electrically and/or communicatively coupled to a top surface of one or more of the memory die packages. The switch enables each memory die in each memory die package to have individual access to an I/O data channel associated with the stack of memory die packages. For example, each memory die in each of the memory die packages is communicatively and/or electrically coupled to the switch. A bond wire electrically couples the switch to a substrate of the memory device. Based on a received control signal, the switch selects which memory die is electrically and/or communicatively coupled to the substrate using the bond wire.

Accordingly, many technical benefits may be realized including, but not limited to, enabling each memory die in a memory device to have individual access to an I/O data channel, reducing or maintaining a height of a memory device by using multiple memory die packages instead of individual memory dies; and increasing the overall electrical performance of the I/O data channel and/or the memory device when compared with memory devices that utilize conventional bond wire architectures.

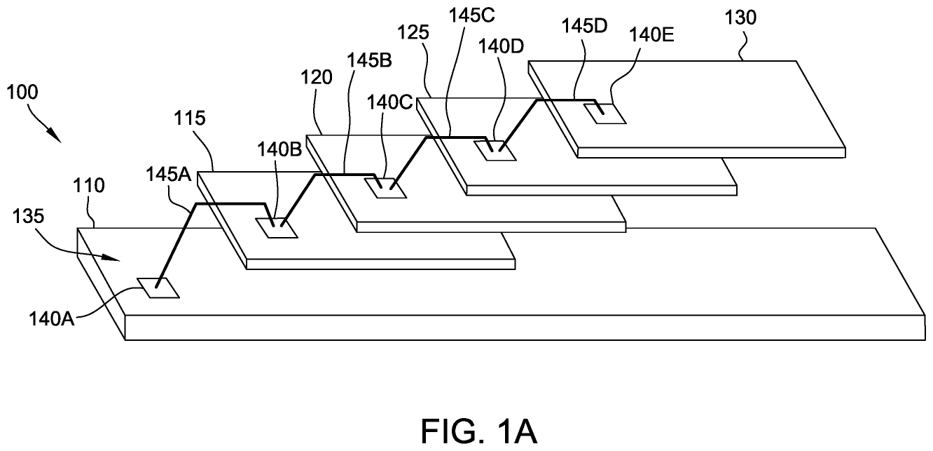

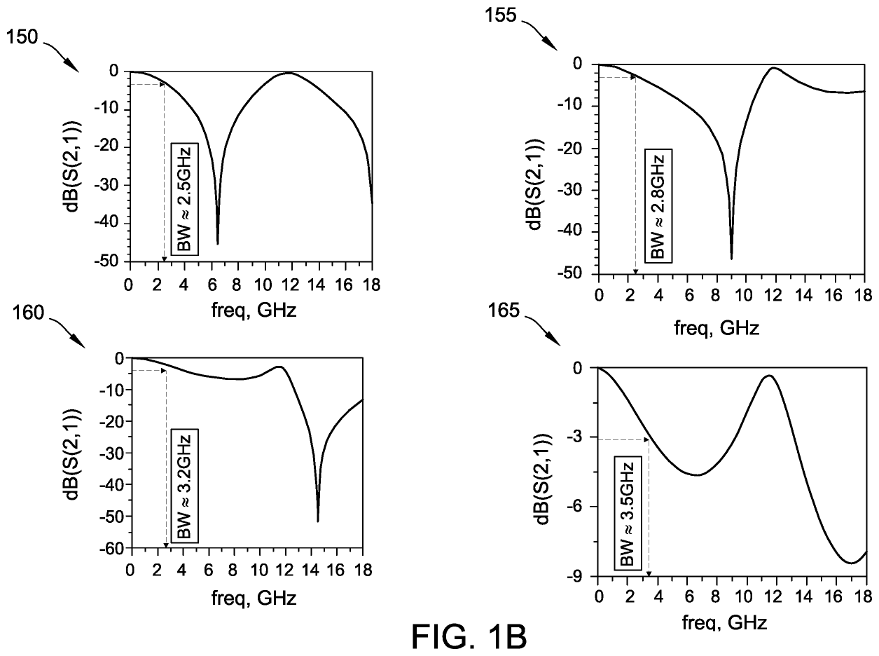

These various benefits and examples will be described in greater detail below with reference to FIG. 1A-FIG. 4.

FIG. 1A illustrates a conventional bond wire architecture for a memory device 100. As shown in FIG. 1A, the memory device 100 includes a substrate 110 and a number of memory dies mounted on the substrate 110. For example, the memory device 100 includes a first memory die 115, a second memory die 120, a third memory die 125 and a fourth memory die 130. The memory device 100 shows one I/O data channel (or just “channel”) 135 through which the substrate 110 and each of the memory dies communicate (e.g., passing data input/output operations and responses back and forth). Each memory die may be, for example, a NAND flash memory die that includes internal circuitry (not shown) for providing volatile or non-volatile storage. It should be understood that FIG. 1A presents separation between the memory dies and between the substrate 110 for purposes of illustration, and that many other circuitry details regarding the memory dies and memory device 100 that are not particularly pertinent to the present disclosure are excluded for case of discussion.

In this example, the substrate 110 and each of the memory dies, include a single pin cap 140A-140E. For example, the substrate 110 includes a pin cap 104A, and each of the memory dies include pin caps 140B through 140E, respectively. These pin caps, or “I/O pads”, are used to connect the internal circuitry of the memory dies to the I/O data channel 135.

Additionally, each of the pin caps are connected, by way of one or two bond wires, with neighboring memory dies or with the substrate 110. The bond wires represent an electrical connection (e.g., a wire) that may be soldered to, or otherwise electrically connected to, the pin caps.

For example, the bond wires are arranged in a cascading pattern in which each of the memory dies are connected to one another. In the example shown in FIG. 1A, a first bond wire 145A connects a pin cap 140A on the surface of the substrate 110 and a pin cap 140B of the first memory die 115. Similarly, a second bond wire 145B connects the pin cap 140B of the first memory die 115 to a pin cap 140C of the second memory die 120, and so on for bond wire 145C connecting pin cap 140C to pin cap 140D, and bond wire 145D connecting pin cap 140D to pin cap 140E. As such, the series of bond wires establishes a data transmission path that is the I/O data channel 135 shared by all of the memory dies and the substrate 110.

Because each of the memory dies share the same I/O data channel 135, the substrate 110 sees multiple die loads in the I/O data channel 135, which negatively impacts the electrical performance (e.g., the bandwidth/speed of operation) of the memory device 100. This is further shown in FIG. 1B.

FIG. 1B shows various graphs that illustrate bandwidth limitations of the bond wire architecture shown in FIG. 1A. For example, each graph shows the bandwidth of the I/O data channel 135 when each memory die drives the I/O data channel 135. In these examples, each graph includes a plot of frequency (in GHz, X-axis) versus insertion loss (S(2,1), in decibels (dB), Y-axis).

The first graph 150 illustrates the bandwidth of the I/O data channel 135 when the first memory die 115 drives the I/O data channel 135. As shown in the first graph 150, the bandwidth of the I/O data channel 135 is approximately 2.5 GHz. The second graph 155 illustrates the bandwidth of the I/O data channel 135 when the second memory die 120 drives the I/O data channel 135. As shown in the second graph 155, the bandwidth of the I/O data channel 135 is approximately 2.8 GHz. The third graph 160 illustrates the bandwidth of the I/O data channel 135 when the third memory die 125 drives the I/O data channel 135. As shown in the third graph 160, the bandwidth of the I/O data channel 135 is approximately 3.2 GHz. The fourth graph 165 illustrates the bandwidth of the I/O data channel 135 when the fourth memory die 130 drives the I/O data channel 135. As shown in the fourth graph 165, the bandwidth of the I/O data channel 135 is approximately 3.5 GHz.

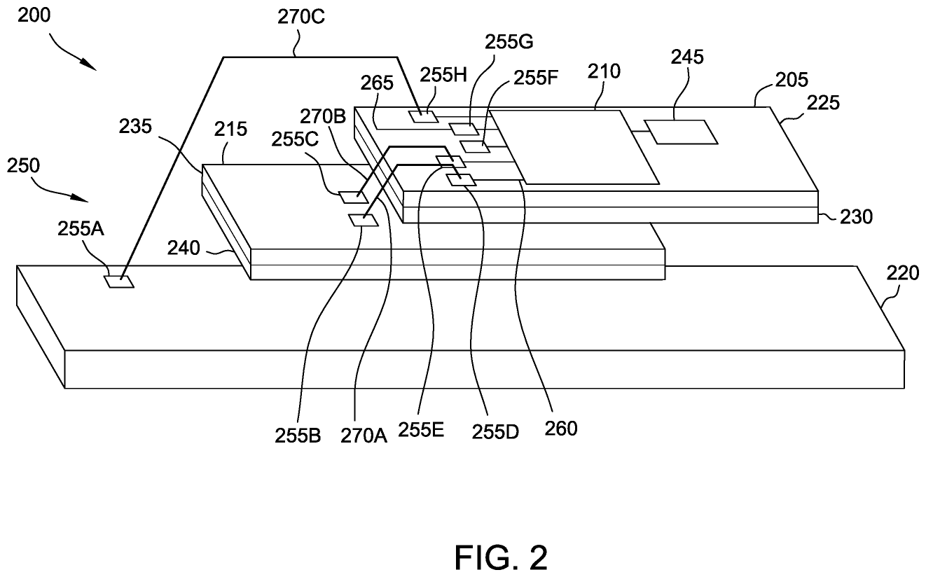

FIG. 2 is an example architecture of a memory device 200 that includes a switch 210 that selectively connects a memory die to a substrate 220 according to an example. Because the switch 210 allows a single die to be coupled to the substrate 220, the bandwidth and/or electrical performance of the memory die stack and/or of an I/O data channel 250 of the memory device 200 increases significantly when compared to the I/O data channel 135 and/or the memory device 100 shown and described with respect to FIG. 1A.

In an example, the memory device 200 includes a first memory die package 205 and a second memory die package 215. Each of the first memory die package 205 and the second memory die package 215 include multiple memory dies that are mounted face to face or are otherwise bonded together.

For example, the first memory die package 205 includes a first memory die 225 bonded with a second memory die 230. Likewise, the second memory die package 215 include a third memory die 235 bonded with a fourth memory die 240. Each of the memory dies in each memory die package may be bonded together in the manner that is shown and described in U.S. Pat. No. 11,004,829, filed Oct. 7, 2019 and titled “Memory Scaling Semiconductor Device”, which is hereby incorporated by reference in its entirety. Although FIG. 2 shows two memory die packages, the memory device 200 may have any number of memory die packages.

Each of the memory die packages may be arranged in a stacked configuration or otherwise form a stack of memory die packages. For example, the first memory die package 205 may be stacked on top of the second memory die package 215.

Additionally, one or more computing components, semiconductor dies, and/or semiconductor packages may be mounted on a top surface of the first memory die package 205. For example, the switch 210 may be mounted or otherwise coupled to the top surface of the first memory die package 205. A controller 245 (or other ASIC) may also be mounted on the top surface of the first memory die package 205. In an example, the controller 245 provides one or more control signals to the switch 210 that causes the switch 210 to selectively couple each of the various memory dies to the substrate 220.

Due to the way in which the memory dies of the memory die packages are fabricated and bonded together, a height of each memory die package may be substantially equivalent to a height of an individual memory die shown and described with respect to FIG. 1. As such, the switch 210 and/or the controller 245 may be mounted on the top surface of the first memory die package 205 without significantly increasing the overall height of the stack of memory die packages and/or the memory device 200 itself.

In an example, the switch 210 may be a multiplexer die (or multiple multiplexer dies), that when activated, enables one memory die of the memory device 200 to be coupled to the substrate 220. For example, each memory die or memory die package may include or otherwise be associated with the I/O data channel 250. The I/O data channel 250 enables the substrate 220 and each of the memory dies communicate.

In the example shown, the substrate 220 and each of the memory die stacks include one or more pin caps. For example, the substrate 220 includes a first pin cap 255A. The second memory die package 215 includes two pin caps-a second pin cap 255B and a third pin cap 255C. In an example, the second pin cap 255B and the third pin cap 255C are provided on a top surface of the third memory die 235. However, the second pin cap 255B may be electrically coupled to the third memory die 235 and the third pin cap 255C may be electrically coupled to the fourth memory die 240. For example, even though the third pin cap 255C is provided on a top surface of the third memory die 235, a via (e.g., a through silicon via (TSV)) and/or one or more transmission lines (or a redistribution layer (RDL)) associated with one or more of the third memory die 235 and/or the fourth memory die 240 may electrically and/or communicatively couple the fourth memory die 240 to the third pin cap 255C.

Additionally, the first memory die package 205 includes five different pin caps provided on a top surface of the first memory die 225. For example, the first memory die package 205 includes a fourth pin cap 255D, a fifth pin cap 255E, a sixth pin cap 255F, a seventh pin cap 255G and an eighth pin cap 255H. In an example, each of the pin caps on the surface of the first memory die 225 of the first memory die package 205 may also be electrically coupled to the switch 210 via one or more traces 260 or wires.

In an example, the sixth pin cap 255F may be electrically coupled to the first memory die 225 and the seventh pin cap 255G may be electrically coupled to the second memory die 230. For example, even though the seventh pin cap 255G is provided on a top surface of the first memory die 225, a via (e.g., a TSV), one or more transmission lines and/or a RDL (e.g., RDL 265) associated with the second memory die 230 and/or the first memory die 225 may electrically and/or communicatively couple the second memory die 230 to the seventh pin cap 255G.

Although a specific number of pin caps have been shown and described on the substrate 220 and each of the memory die packages, the substrate 220 and each of the memory die packages may include any number of pin caps. Additionally, each of the pin caps may be positioned at any location on the substrate 220 and/or each of the memory die packages. For example, a TSV, a transmission line and/or a RDL may enable the various pin caps to be provided at any number of locations on the surface of the first memory die 225 and/or the third memory die 235.

As shown in FIG. 2, various bond wires electrically couple the various pin caps (and the various memory dies associated with each of the pin caps) to the switch 210. For example, a first bond wire 270A may electrically couple the second pin cap 255B to the fourth pin cap 255D. Likewise, a second bond wire 270B may electrically couple the third pin cap 255C to the fifth pin cap 255E. The fourth pin cap 255D and the fifth pin cap 255E may also be electrically coupled to the switch 210 using additional bond wires and/or traces 260. Likewise, each of the sixth pin cap 255F and the seventh pin cap 255G may be electrically coupled to the switch 210 using bond wires and/or traces 260.

The switch 210 is also communicatively coupled to the eighth pin pad 255H. For example a bond wire and/or a trace electrically couples the switch 210 to the eighth pin pad 255H. As shown in FIG. 2, a third bond wire 270C establishes a data transmission path from the eighth pin pad 255H to the first pin pad 255A on the substrate 220. Based on this configuration, the switch 210 may control which of the memory dies drive the I/O data channel 250 and is coupled to the substrate 220.

For example and based on a control signal from the controller 245, the switch 210 may establish or otherwise enable a transmission path between the fourth memory die 240 and the substrate 220. As such, the switch 210 may establish a communication path between the fourth memory die 240, the third pin cap 255C, the second bond wire 270B, and the fifth pin cap 255E. The switch 210 then enables the fourth memory die 240 to be connected to the substrate using the eighth pin cap 255H, the third bond wire 270C and the first pin cap 255A.

In this example, each of the memory dies may share the same I/O data channel 250, however, the switch 210 enables each of the memory dies to individually/separately access the I/O data channel 250. As such, the electrical performance (e.g., the bandwidth/speed of operation) of the I/O data channel 250 and/or the memory device 200 is improved-especially when compared against the electrical performance of the I/O data channel 135 and/or the memory device 100 shown and described with respect to FIG. 1A.

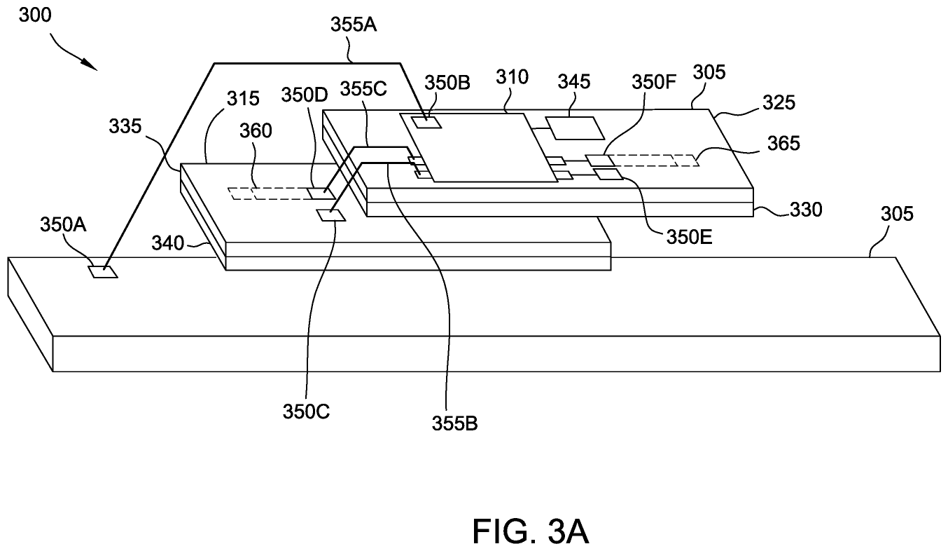

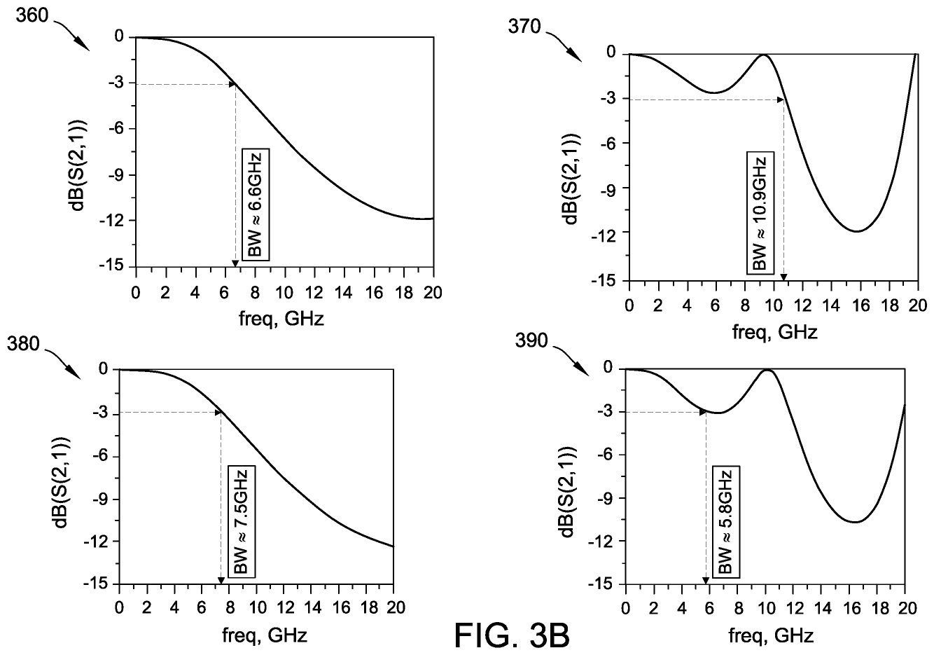

FIG. 3A illustrates another example architecture of a memory device 300 that includes a switch 310 that selectively connects a memory die to a substrate 320 according to an example. In an example, the memory device 300 may be similar to the memory device 200 shown and described with respect to FIG. 2.

For example, the memory device 300 includes a first memory die package 305 and a second memory die package 315. Each of the first memory die package 305 and the second memory die package 315 include multiple memory dies that are mounted face to face or are otherwise bonded together. For example, the first memory die package 305 includes a first memory die 325 bonded with a second memory die 330. Likewise, the second memory die package 315 include a third memory die 335 bonded with a fourth memory die 340. Although FIG. 3 shows two memory die packages, the memory device 300 may have any number of memory die packages.

Each of the memory die packages may be arranged in a stacked configuration or otherwise form a stack of memory die packages. For example, the first memory die package 305 may be stacked on top of the second memory die package 315.

Additionally, one or more computing components, semiconductor packages and/or integrated circuits may be mounted on a top surface of the first memory die package 305. For example, the switch 310 may be mounted or otherwise coupled to the top surface of the first memory die package 305. Likewise, a controller 345 or other integrated circuit may also be mounted on the top surface of the first memory die package 305. In an example, the controller 345 provides one or more control signals to the switch 310 that causes the switch 310 to selectively couple each of the various memory dies to the substrate 320.

In the example shown in FIG. 3A, and similar to the example shown in FIG. 2, the substrate 320 and each of the memory die stacks include one or more pin caps. For example, the substrate 320 includes a first pin cap 350A. The first pin cap 350A may be electrically coupled to the switch 310 via a first bond wire 355A. For example, the switch 310 may include or otherwise be associated with a second pin cap 350B (or other connection pad/point) that enables the switch 310 to be electrically coupled to the first pin cap 350A on the substrate 305 using the first bond wire 355A.

In an example, the second memory die package 315 includes two pin caps-a third pin cap 350C and a fourth pin cap 350D. The third pin cap 350C and the fourth pin cap 350D may be provided on a top surface of the third memory die 335. In an example, the third pin cap 350C may be electrically coupled to the third memory die 335 and the fourth pin cap 350D may be electrically coupled to the fourth memory die 340.

For example, even though the fourth pin cap 350D is provided on a top surface of the third memory die 335, a via (e.g., a TSV), one or more transmission lines and/or a RDL 360 associated with the fourth memory die 340 may electrically and/or communicatively couple the fourth memory die 340 to the fourth pin cap 350D.

In the example shown in FIG. 3A, a second bond wire 355B electrically couples the third memory die 335 (e.g. using the third pin cap 350C) to the switch 310. Likewise, a third bond wire 355C electrically couples the fourth memory die 340 to the switch 310.

The first memory die package 305 may also include various pin caps. For example, the first memory die package 305 includes two pin caps-a fifth pin cap 350E and a sixth pin cap 350F. The fifth pin cap 350E and the sixth pin cap 350F may be provided on a top surface of the first memory die 325. In an example, the fifth pin cap 350E may be electrically coupled to the first memory die 325 and the sixth pin cap 350F may be electrically coupled to the second memory die 330.

For example, even though the sixth pin cap 350F is provided on a top surface of the first memory die 325, a via (e.g., a TSV) and/or a RDL 365 (or other such transmission line) associated with the second memory die 330 may electrically and/or communicatively couple the second memory die 330 to the sixth pin cap 350F. In an example, each of the fifth pin cap 350E and the sixth pin cap 350F are electrically coupled to the switch 310.

As with the example shown and described with respect to FIG. 2, the switch 310 establishes a data transmission path from the various pin caps to the substrate 305. For example and based on a control signal from the controller 345, the switch 310 may establish or otherwise enable a transmission path between the fourth memory die 340 and the substrate 305 using the RDL 360, the fourth pin cap 350D, the third bond wire 355C and the first bond wire 355A.

In an example, each of the memory dies of the memory device 300 may share the same I/O data channel. However, the switch 310 enables each of the memory dies to access the I/O data channel separately. As such, the electrical performance (e.g., the bandwidth/speed of operation) of the I/O data channel and/or memory device 300 is improved-especially when compared against the electrical performance of the I/O data channel 135 and/or memory device 100 shown and described with respect to FIG. 1A.

FIG. 3B shows various graphs that illustrate bandwidth performance of the memory device architecture shown in FIG. 3A. When comparing the bandwidth performance of the various bond wires and/or the I/O data channel in FIG. 2 and FIG. 3A with the bandwidth performance of the various bond wires and/or the I/O data channel 135 of FIG. 1A, the memory device architecture shown in FIG. 3A significantly improves the electrical performance of the memory device 300.

Like the graphs in FIG. 1B, each graph in FIG. 3B shows the bandwidth of the I/O data channel (e.g., the I/O data channel 250 (FIG. 2)) when each memory die drives the I/O data channel. In these examples, each graph includes a plot of frequency (in GHz, X-axis) versus insertion loss (S(2,1), in decibels (dB), Y-axis).

The first graph 360 illustrates the bandwidth of the I/O data channel when the first memory die 325 drives the I/O data channel. As shown in the first graph 360, the bandwidth of the I/O data channel is approximately 6.6 GHz. The second graph 370 illustrates the bandwidth of the I/O data channel when the second memory die 330 drives the I/O data channel. As shown in the second graph 370, the bandwidth of the I/O data channel is approximately 10.9 GHz. The third graph 380 illustrates the bandwidth of the I/O data channel when the third memory die 335 drives the I/O data channel. As shown in the third graph 380, the bandwidth of the I/O data channel is approximately 7.5 GHz. The fourth graph 390 illustrates the bandwidth of the I/O data channel when the fourth memory die 340 drives the I/O data channel. As shown in the fourth graph 390, the bandwidth of the I/O data channel is approximately 5.8 GHz.

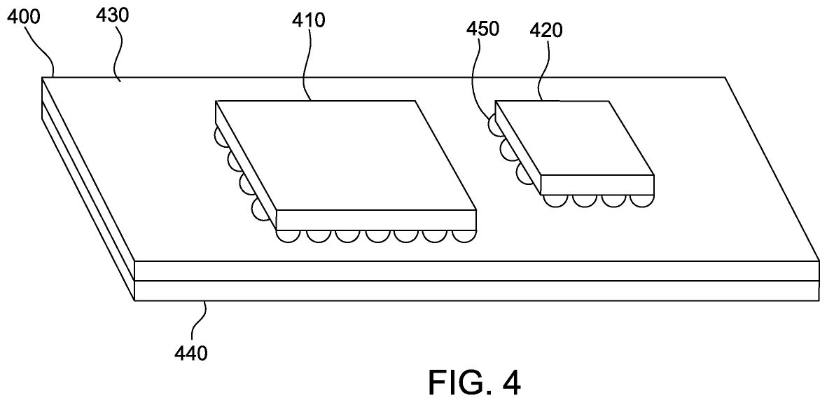

FIG. 4 illustrates a switch 410 and an integrated circuit 420 being surface mounted to a memory die package 400 according to an example. In an example, the memory die package 400 may be similar to the first memory die package 205 and/or the second memory die package 215 shown and described with respect to FIG. 2.

In an example, the memory die package 400 includes a first memory die 430 and a second memory die 440. Each of the first memory die 430 and the second memory die 440 may be bonded or otherwise coupled together to form the memory die package 400 such as previously described. Additionally, the switch 410 and/or the integrated circuit 420 may be surface mounted to a top surface of the memory die package 400 using one or more solder balls 450, bond pads and/or connection points. For example, the top surface of the memory die package 400 may include one or more bond pads that receive solder balls 450 of a flip-chip die or package (e.g., the switch 410). As such, the switch 410 and/or the integrated circuit 420 may be surface mounted to the top surface of the memory die package 400.

In this example, one or more vias (e.g., TSVs) and/or associated signal lines (e.g., traces) may directly connect the first memory die 430 and/or the second memory die 440 to the switch 410 and/or the integrated circuit 420. Similarly, one or more memory dies of a second memory die package may also be directly connected to the switch 410 using a one or more TSVs and/or associated signal lines. Thus, the switch 410 and/or the integrated circuit may be electrically and/or communicatively coupled to the memory die package 400 using bond wires, solder balls and/or other connection points.

Based on the above, examples of the present disclosure describe a memory device, comprising: a first memory die and a second memory die bonded together to form a first memory die package; a third memory die and a fourth memory die bonded together to form a second memory die package, the second memory die package and the first memory die package forming a stack of memory die packages; a switch electrically coupled to a top surface of the first memory die package; a first electrical connection electrically coupling the first memory die to the switch; a second electrical connection electrically coupling the second memory die to the switch; a third electrical connection electrically coupling the third memory die to the switch; a fourth electrical connection electrically coupling the fourth memory die to the switch; and a bond wire electrically coupling the switch to a substrate of the memory device. In an example, the switch selectively electrically couples one of the first memory die, the second memory die, the third memory die and the fourth memory die to the substrate using the bond wire. In an example, the memory device also includes a first pin pad and a second pin pad provided on the top surface of the first memory package, wherein: the first electrical connection extends from the first pin pad; and the second electrical connection extends from the second pin pad. In an example, the memory device also includes a redistribution layer electrically coupling the second memory die to the second pin pad. In an example, at least one of the first electrical connection, the second electrical connection, the third electrical connection and the fourth electrical connection is a bond wire. In an example, at least one of the first electrical connection, the second electrical connection, the third electrical connection and the fourth electrical connection is a bond pad. In an example, the switch is a multiplexer. In an example, the memory device also includes a controller that provides a control signal to the switch, the control signal indicating which of the first memory die, the second memory die, the third memory die and the fourth memory die is electrically coupled to the substrate.

In other examples the present disclosure describes a semiconductor package, comprising: a first semiconductor die and a second semiconductor die bonded together to form a first package; a third semiconductor die and a fourth semiconductor die bonded together to form a second package, the second package being stacked with the first package; a switch electrically coupled to a top surface of the first package; a plurality of electrical connections electrically coupling the first semiconductor die, the second semiconductor die, the third semiconductor die and the fourth semiconductor die to the switch; and a bond wire electrically coupling the switch to a substrate. In an example, the switch selectively electrically couples one of the semiconductor dies to the substrate using the bond wire. In an example, the semiconductor package also includes a first pin pad and a second pin pad provided on the top surface of the first memory package, wherein: the first electrical connection extends from the first pin pad; and the second electrical connection extends from the second pin pad. In an example, the semiconductor package includes a redistribution layer electrically coupling the second memory die to the second pin pad. In an example, at least one of the first electrical connection, the second electrical connection, the third electrical connection and the fourth electrical connection is a bond wire. In an example, at least one of the first electrical connection, the second electrical connection, the third electrical connection and the fourth electrical connection is a bond pad. In an example, the switch is a multiplexer. In an example, the semiconductor device also includes a controller that provides a control signal to the switch, the control signal indicating which of the first memory die, the second memory die, the third memory die and the fourth memory die is electrically coupled to the substrate.

Examples of the present disclosure also describe a memory device, comprising: a controller means; a first semiconductor package having a first semiconductor die bonded with a second semiconductor die; a second semiconductor package having a third semiconductor die bonded with a fourth semiconductor die, the second semiconductor package and the first semiconductor package arranged in a stacked configuration; and a switching means electrically coupled to the first semiconductor package and the second semiconductor package, the switching means selectively electrically coupling each of the first semiconductor die, the second semiconductor die, the third semiconductor die and the fourth semiconductor die to a substrate of the memory device using a bond wire that electrically couples the switching means to the substrate. In an example, the switching means is electrically coupled to the first semiconductor package using a plurality of bond wires. In an example, the switching means is electrically coupled to the first semiconductor package using a plurality of bond pads. In an example, the switching means is a multiplexer.

The description and illustration of one or more aspects provided in the present disclosure are not intended to limit or restrict the scope of the disclosure in any way. The aspects, examples, and details provided in this disclosure are considered sufficient to convey possession and enable others to make and use the best mode of claimed disclosure.

The claimed disclosure should not be construed as being limited to any aspect, example, or detail provided in this disclosure. Regardless of whether shown and described in combination or separately, the various features (both structural and methodological) are intended to be selectively rearranged, included or omitted to produce an example with a particular set of features. Having been provided with the description and illustration of the present application, one skilled in the art may envision variations, modifications, and alternate aspects falling within the spirit of the broader aspects of the general inventive concept embodied in this application that do not depart from the broader scope of the claimed disclosure.

Aspects of the present disclosure have been described above with reference to schematic flowchart diagrams and/or schematic block diagrams of methods, apparatuses, systems, and computer program products according to examples of the disclosure. It will be understood that each block of the schematic flowchart diagrams and/or schematic block diagrams, and combinations of blocks in the schematic flowchart diagrams and/or schematic block diagrams, can be implemented by computer program instructions. These computer program instructions may be provided to a processor of a computer or other programmable data processing apparatus to produce a machine, such that the instructions, which execute by way of the processor or other programmable data processing apparatus, create means for implementing the functions and/or acts specified in the schematic flowchart diagrams and/or schematic block diagrams block or blocks.

References to an element herein using a designation such as “first,” “second,” and so forth does not generally limit the quantity or order of those elements. Rather, these designations may be used as a method of distinguishing between two or more elements or instances of an element. Thus, reference to first and second elements does not mean that only two elements may be used or that the first element precedes the second element. Additionally, unless otherwise stated, a set of elements may include one or more elements.

Terminology in the form of “at least one of A, B, or C” or “A, B, C, or any combination thereof” used in the description or the claims means “A or B or C or any combination of these elements.” For example, this terminology may include A, or B, or C, or A and B, or A and C, or A and B and C, or 2A, or 2B, or 2C, or 2A and B, and so on. As an additional example, “at least one of: A, B, or C” is intended to cover A, B, C. A-B, A-C, B-C, and A-B-C, as well as multiples of the same members. Likewise, “at least one of: A, B, and C” is intended to cover A, B, C. A-B, A-C, B-C, and A-B-C, as well as multiples of the same members.

Similarly, as used herein, a phrase referring to a list of items linked with “and/or” refers to any combination of the items. As an example, “A and/or B” is intended to cover A alone, B alone, or A and B together. As another example, “A, B and/or C” is intended to cover A alone, B alone, C alone, A and B together, A and C together, B and C together, or A, B, and C together.

What is claimed is:

1. A memory device, comprising:
a first memory die and a second memory die bonded together to form a first memory die package;
a third memory die and a fourth memory die bonded together to form a second memory die package, the second memory die package and the first memory die package forming a stack of memory die packages;
a switch electrically coupled to a top surface of the first memory die package;
a first electrical connection electrically coupling the first memory die to the switch;
a second electrical connection electrically coupling the second memory die to the switch;
a third electrical connection electrically coupling the third memory die to the switch;
a fourth electrical connection electrically coupling the fourth memory die to the switch; and
a bond wire electrically coupling the switch to a substrate of the memory device.

2. The memory device of claim 1, wherein the switch selectively electrically couples one of the first memory die, the second memory die, the third memory die and the fourth memory die to the substrate using the bond wire.

3. The memory device of claim 1, further comprising a first pin pad and a second pin pad provided on the top surface of the first memory package, wherein:
the first electrical connection extends from the first pin pad; and
the second electrical connection extends from the second pin pad.

4. The memory device of claim 3, further comprising a redistribution layer electrically coupling the second memory die to the second pin pad.

5. The memory device of claim 1, wherein at least one of the first electrical connection, the second electrical connection, the third electrical connection and the fourth electrical connection is a bond wire.

6. The memory device of claim 1, wherein at least one of the first electrical connection, the second electrical connection, the third electrical connection and the fourth electrical connection is a bond pad.

7. The memory device of claim 1, wherein the switch is a multiplexer.

8. The memory device of claim 1, further comprising a controller that provides a control signal to the switch, the control signal indicating which of the first memory die, the second memory die, the third memory die and the fourth memory die is electrically coupled to the substrate.

9. A semiconductor package, comprising:
a first semiconductor die and a second semiconductor die bonded together to form a first package;
a third semiconductor die and a fourth semiconductor die bonded together to form a second package, the second package being stacked with the first package;
a switch electrically coupled to a top surface of the first package;
a plurality of electrical connections electrically coupling the first semiconductor die, the second semiconductor die, the third semiconductor die and the fourth semiconductor die to the switch; and
a bond wire electrically coupling the switch to a substrate.

10. The semiconductor package of claim 9, wherein the switch selectively electrically couples one of the semiconductor dies to the substrate using the bond wire.

11. The semiconductor package of claim 9, further comprising further comprising a first pin pad and a second pin pad provided on the top surface of the first memory package, wherein:
the first electrical connection extends from the first pin pad; and
the second electrical connection extends from the second pin pad.

12. The semiconductor package of claim 11, further comprising a redistribution layer electrically coupling the second memory die to the second pin pad.

13. The semiconductor package of claim 9, wherein at least one of the first electrical connection, the second electrical connection, the third electrical connection and the fourth electrical connection is a bond wire.

14. The semiconductor package of claim 9, wherein at least one of the first electrical connection, the second electrical connection, the third electrical connection and the fourth electrical connection is a bond pad.

15. The semiconductor package of claim 9, wherein the switch is a multiplexer.

16. The semiconductor package of claim 9, further comprising a controller that provides a control signal to the switch, the control signal indicating which of the first memory die, the second memory die, the third memory die and the fourth memory die is electrically coupled to the substrate.

17. A memory device, comprising:
a controller means;
a first semiconductor package having a first semiconductor die bonded with a second semiconductor die;
a second semiconductor package having a third semiconductor die bonded with a fourth semiconductor die, the second semiconductor package and the first semiconductor package arranged in a stacked configuration; and
a switching means electrically coupled to the first semiconductor package and the second semiconductor package, the switching means selectively electrically coupling each of the first semiconductor die, the second semiconductor die, the third semiconductor die and the fourth semiconductor die to a substrate of the memory device using a bond wire that electrically couples the switching means to the substrate.

18. The memory device of claim 17, wherein the switching means is electrically coupled to the first semiconductor package using a plurality of bond wires.

19. The memory device of claim 17, wherein the switching means is electrically coupled to the first semiconductor package using a plurality of bond pads.

20. The memory device of claim 17, wherein the switching means is a multiplexer.
